(19) United States
(12) Patent Application Publication
(10) Pub. No.: US 2024/0420916 A1
(43) Pub. Date: Dec. 19, 2024

(54) WAFER EDGE INSPECTION OF CHARGED PARTICLE INSPECTION SYSTEM

(71) Applicant: ASML Netherlands B.V., Veldhoven (NL)

(72) Inventors: Xiaoyu JI, San Jose, CA (US); Zizhou GONG, San Jose, CA (US); Weiming REN, San Jose, CA (US)

(73) Assignee: ASML Netherlands B.V., Veldhoven (NL)

(21) Appl. No.: 18/706,592

(22) PCT Filed: Oct. 5, 2022
(86) PCT No.: PCT/EP2022/077738

§ 371 Date: May 1, 2024

Related U.S. Application Data
(60) Provisional application No. 63/274,918, filed on Nov. 2, 2021.

(51) Int. Cl. H01J 37/20

(52) U.S. Cl. CPC H01J 37/20; H01J 2237/2007; H01J 2237/20235; H01J 2237/204

(57) ABSTRACT

An improved method of wafer inspection is disclosed. The improved method includes a non-transitory computer-readable medium storing a set of instructions that are executable by at least one processor of a device to cause the device to perform a method comprising: placing the wafer at a location on a stage; moving one or more movable segments of a conductive ring inward in a radial direction to enable the conductive ring to be within a predetermined distance from an edge of the wafer; and adjusting a voltage applied to the conductive ring or to a voltage applied to the wafer so that to enable the voltage applied to the conductive ring to be substantially equal to the voltage applied to the wafer to provide a substantially consistent electric field across an inner portion of the conductive ring and an outer portion of the wafer.

### CROSS-REFERENCE TO RELATED APPLICATIONS

This application claims priority of U.S. application 63/274,918 which was filed on 2 Nov. 2021 and which is incorporated herein in its entirety by reference.

### FIELD

The description herein relates to the field of charged particle beam apparatus, and more particularly to wafer edge inspection for a charged particle inspection system.

### BACKGROUND

A charged particle beam apparatus is able to produce a 2-dimensional image of a wafer substrate by detecting secondary electrons, backscattered electrons, mirror electrons, or other kinds of electrons from the surface of the wafer substrate upon impingement by a charged particle beam generated by the charged particle beam apparatus. Various charged particle beam apparatuses are used on semiconductor wafers in semiconductor industry for various purposes such as wafer processing (e.g., e-beam direct write lithography system), process monitoring (e.g., critical dimension scanning electron microscope (CD-SEM)), wafer inspection (e.g., e-beam inspection system), defect analysis (e.g., defect review SEM, or say DR-SEM and Focused Ion Beam system, or say FIB), etc.

During wafer inspection, any potential defects in the wafer can be discovered and removed so that flawless structures to be formed in the wafer at a later stage. During the wafer inspection process, the wafer can be placed inside of a conductive ring, also referred to as a high voltage (HV) ring structure on a wafer holder (stage). The conductive ring may also be referred to as a compensation ring. In conventional systems, there is gap between the conductive ring and the edge of the wafer, which can create a distorted electric potential near the wafer edge during the inspection process.

### SUMMARY

Embodiments of the present disclosure provide systems and methods for inspecting a wafer.

Some embodiments provide a method of inspecting a wafer comprising: placing the wafer at a location on a stage; moving one or more movable segments of a conductive ring inward in a radial direction to enable the conductive ring to be within a predetermined distance from an edge of the wafer; and adjusting a voltage applied to the conductive ring to enable the voltage applied to the conductive ring to be substantially equal to the voltage applied to the wafer to provide a substantially consistent electric field across an inner portion of the conductive ring and an outer portion of the wafer.

Some embodiments provide a system of inspecting a wafer, comprising: a stage configured to support a wafer having a wafer edge; a conductive ring of the stage, the conductive ring comprising: one or more movable segments configured to move radially inward to enable the conductive ring to be moved to be within a predetermined distance from the wafer edge; and a controller including circuitry configured to adjust a voltage applied to the conductive ring or to a voltage applied to the wafer to enable the voltage applied to the conductive ring to be substantially similar to the voltage applied to the wafer to provide a substantially consistent electric field across an inner portion of the conductive ring and an outer portion of the wafer.

A non-transitory computer-readable medium storing a set of instructions that are executable by at least one processor of a device to cause the device to perform a method comprising: placing the wafer at a location on a stage; moving one or more movable segments of a conductive ring inward in a radial direction to enable the conductive ring to be within a predetermined distance from an edge of the wafer; and adjusting a voltage applied to the conductive ring or to a voltage applied to the wafer so that to enable the voltage applied to the conductive ring to be substantially equal to the voltage applied to the wafer to provide a substantially consistent electric field across an inner portion of the conductive ring and an outer portion of the wafer.

### BRIEF DESCRIPTION OF THE DRAWINGS

FIG. 1 is a schematic diagram illustrating an example electron beam inspection (EBI) system, consistent with some embodiments of the present disclosure.

FIG. 2 is a schematic diagram illustrating an example electron beam tool, consistent with some embodiments of the present disclosure that may be a part of the example electron beam inspection system of FIG. 1.

FIG. 3A is an illustration of a top view of an example system during wafer loading, consistent with some embodiments of the present disclosure.

FIG. 3B is an illustration of a top view of an example system after wafer loading, consistent with some embodiments of the present disclosure.

FIG. 4A is an illustration of a cross-sectional view of an example system during wafer loading, consistent with some embodiments of the present disclosure.

FIG. 4B is an illustration of a cross-sectional view of an example system after wafer loading, consistent with some embodiments of the present disclosure.

FIG. 5 is a schematic diagram illustrating an example controller and example sensors coupled to work with the system of 3A, 3B, 4A, or 4B, consistent with some embodiments of the present disclosure.

FIG. 6 is a flowchart illustrating an example method for inspecting a wafer, consistent with some embodiments of the present disclosure.

FIG. 7 is a flowchart illustrating an example method for eliminating a distorted e-field near the wafer edge, consistent with some embodiments of the present disclosure.

### DETAILED DESCRIPTION

Reference will now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the subject matter recited in the appended claims. Without limiting the scope of the present disclosure, some embodiments may be described in the context of providing detection systems and detection methods in systems utilizing electron beams (“e-beams”). However, the disclosure is not so limited. Other types of charged-particle beams (e.g., including protons, ions, muons, or any other particle carrying electric charges) may be similarly applied. Furthermore, systems and methods for detection may be used in other imaging systems, such as optical imaging, photon detection, x-ray detection, ion detection, or the like.

Electronic devices are constructed of circuits formed on a piece of semiconductor material called a substrate. The semiconductor material may include, for example, silicon, gallium arsenide, indium phosphide, or silicon germanium, or the like. Many circuits may be formed together on the same piece of silicon and are called integrated circuits or ICs. The size of these circuits has decreased dramatically so that many more of them can be fit on the substrate. For example, an IC chip in a smartphone can be as small as a thumbnail and yet may include over 2 billion transistors, the size of each transistor being less than 1/1000th the size of a human hair.

Making these ICs with extremely small structures or components is a complex, time-consuming, and expensive process, often involving hundreds of individual steps. Errors in even one step have the potential to result in defects in the finished IC, rendering it useless. Thus, one goal of the manufacturing process is to avoid such defects to maximize the number of functional ICs made in the process; that is, to improve the overall yield of the process.

One component of improving yield is monitoring the chip-making process to ensure that it is producing a sufficient number of functional integrated circuits. One way to monitor the process is to inspect the chip circuit structures at various stages of their formation. Inspection can be carried out using a scanning charged-particle microscope (“SCPM”). For example, an SCPM may be a scanning electron microscope (SEM). A SCPM can be used to image these extremely small structures, in effect, taking a “picture” of the structures of the wafer. The image can be used to determine if the structure was formed properly in the proper location. If the structure is defective, then the process can be adjusted, so the defect is less likely to recur.

The working principle of a SEM is similar to a camera. A camera takes a picture by receiving and recording intensity of light reflected or emitted from people or objects. A SEM takes a “picture” by receiving and recording energies or quantities of electrons reflected or emitted from the structures of the wafer. Before taking such a “picture,” an electron beam may be projected onto the structures, and when the electrons are reflected or emitted (“exiting”) from the structures (e.g., from the wafer surface, from the structures underneath the wafer surface, or both), a detector of the SEM may receive and record the energies or quantities of those electrons to generate an inspection image. To take such a “picture.” the electron beam may scan through the wafer (e.g., in a line-by-line or zig-zag manner), and the detector may receive exiting electrons coming from a region under electron-beam projection (referred to as a “beam spot”). The detector may receive and record exiting electrons from each beam spot one at a time and join the information recorded for all the beam spots to generate the inspection image. Some SEMs use a single electron beam (referred to as a “single-beam SEM”) to take a single “picture” to generate the inspection image, while some SEMs use multiple electron beams (referred to as a “multi-beam SEM”) to take multiple “sub-pictures” of the wafer in parallel and stitch them together to generate the inspection image. By using multiple electron beams, the SEM may provide more electron beams onto the structures for obtaining these multiple “sub-pictures,” resulting in more electrons exiting from the structures. Accordingly, the detector may receive more exiting electrons simultaneously and generate inspection images of the structures of the wafer with higher efficiency and faster speed.

Typically, the structures are made on a substrate (e.g., a silicon substrate) that is placed on a platform, referred to as a stage or an electric chuck (e-chuck), for imaging. The platform can include a wafer holder that surrounds the wafer. In conventional wafer platform systems, when the wafer is placed in the wafer holder, there is a gap between the wafer edge and an inner circle of the wafer holder. This gap creates a discontinuity or distortion of an e-field near the wafer edge, which impacts the performance of the SEM. In particular, the distortion of the E-field can cause an electron beam to defocus, deflect, distort, thereby impacting any corresponding image of the wafer. In some instances, a high-voltage (HV) ring structure located in the gap can be used to supply an additional voltage so that the electric potential near the wafer edge is more uniform. However, the conductive ring may be fixed and the gap between the wafer edge and the ring cannot be adjusted. Problems can occur when the wafer is not situated perfectly within the ring structure, such as situations when the wafer is off center. In such situations, the conductive ring may need to provide different compensation voltages at different locations. Moreover, in at least some conventional systems, the conductive ring may be below the wafer surface, thereby requiring a very high compensation voltage (several kV) to obtain a desired compensation performance.

In general, in current conventional systems, the distorted e-field cannot be fully compensated or additional compensation elements in the electron optics system must be adjusted to reduce the impact on image quality to an acceptable level. Thus, current systems and processes of wafer inspection can result in many errors due to a non-uniform e-field near the wafer edge.

To improve the wafer inspection process, it may be advantageous to eliminate or minimize the distorted e-field near the wafer edge. According to at least some embodiments of the present disclosure, an adjustable segmented electrically conductive ring that surrounds the wafer is introduced. In some examples, each of the adjustable segments can move radially inward/outward or up/down. In some examples, a few of the segments can be stationary or fixed and the rest of the segments can be movable and the movable segments may be configured to move the wafer to contact the fixed segments. For example, at least some of the segments can be moved radially outward to create an area for a wafer to be placed. After placement of the wafer, the segments can be moved radially inward and up/down until each segment contacts or is as near as possible to the wafer edge and is planar with the exposed surface of the wafer. Advantageously, the above-mentioned process makes the electric potential distribution near the wafer edge more uniform, thereby improving the imaging capabilities near the edge of the wafer.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

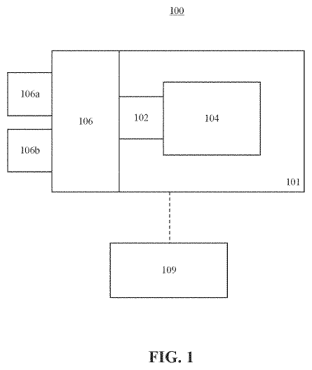

FIG. 1 illustrates an exemplary electron beam inspection (EBI) system 100 consistent with some embodiments of the present disclosure. EBI system 100 may be used for imaging. As shown in FIG. 1, EBI system 100 includes a main chamber 101, a load/lock chamber 102, a beam tool 104, and an equipment front end module (EFEM) 106. Beam tool 104 is located within main chamber 101.

EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by beam tool 104. Beam tool 104 may be a single-beam system or a multi-beam system.

A controller 109 is electronically connected to beam tool 104. Controller 109 may be a computer configured to execute various controls of EBI system 100. While controller—109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

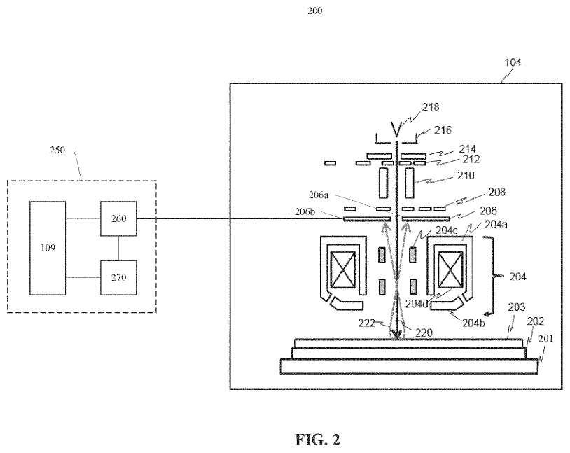

FIG. 2 illustrates an example imaging system 200 according to embodiments of the present disclosure. Electron beam tool 104 of FIG. 2 may be configured for use in EBI system 100. Electron beam tool 104 may be a single beam apparatus or a multi-beam apparatus. As shown in FIG. 2, electron beam tool 104 includes a motorized sample stage 201, and a wafer holder 202 supported by motorized sample stage 201 to hold a wafer 203 to be inspected. Electron beam tool 104 further includes an objective lens assembly 204, an electron detector 206 (which includes electron sensor surfaces 206a and 206b), an objective aperture 208, a condenser lens 210, a beam limit aperture 212, a gun aperture 214, an anode 216, and a cathode 218. It is appreciated that the electron detector 206 can also be a single piece, e.g., an annular type. Objective lens assembly 204, in some embodiments, may include a modified swing objective retarding immersion lens (SORIL), which includes a pole piece 204a, a control electrode 204b, a deflector 204c, and an exciting coil 204d. Electron beam tool 104 may additionally include an Energy Dispersive X-ray Spectrometer (EDS) detector (not shown) to characterize the materials on wafer 203.

A primary electron beam 220 is emitted from cathode 218 by applying an acceleration voltage between anode 216 and cathode 218. Primary electron beam 220 passes through gun aperture 214 and beam limit aperture 212, both of which may determine the size of electron beam entering condenser lens 210, which resides below beam limit aperture 212. —Condenser lens 210 focuses primary electron beam 220 before the beam enters objective aperture 208 to set the size of the electron beam before entering objective lens assembly 204. Deflector 204c deflects primary electron beam 220 to facilitate beam scanning on the wafer. For example, in a scanning process, deflector 204c may be controlled to deflect primary electron beam 220 sequentially onto different locations of top surface of wafer 203 at different time points, to provide data for image reconstruction for different parts of wafer 203. Moreover, deflector 204c may also be controlled to deflect primary electron beam 220 onto different sides of wafer 203 at a particular location, at different time points, to provide data for stereo image reconstruction of the wafer structure at that location. Further, in some embodiments,

anode 216 and cathode 218 may generate multiple primary electron beams 220, and electron beam tool 104 may include a plurality of deflectors 204c to project the multiple primary electron beams 220 to different parts/sides of the wafer at the same time, to provide data for image reconstruction for different parts of wafer 203.

Exciting coil 204d and pole piece 204a generate a magnetic field that begins at one end of pole piece 204a and terminates at the other end of pole piece 204a. A part of wafer 203 being scanned by primary electron beam 220 may be immersed in the magnetic field and may be electrically charged, which, in turn, creates an e-field. The e-field reduces the energy of impinging primary electron beam 220 near the surface of wafer 203 before it collides with wafer 203. Control electrode 204b, being electrically isolated from pole piece 204a, controls an e-field on wafer 203 to prevent micro-arching of wafer 203 and to ensure proper beam focus.

A secondary electron beam 222 may be emitted from the part of wafer 203 upon receiving primary electron beam 220. Secondary electron beam 222 may form a beam spot on sensor surfaces 206a and 206b of electron detector 206. Electron detector 206 may generate a signal (e.g., a voltage, a current, or the like.) that represents an intensity of the beam spot and provide the signal to an image processing system 250. The intensity of secondary electron beam 222, and the resultant beam spot, may vary according to the external or internal structure of wafer 203. Moreover, as discussed above, primary electron beam 220 may be projected onto different locations of the top surface of the wafer or different sides of the wafer at a particular location, to generate secondary electron beam 222 (and the resultant beam spot) of different intensities. Therefore, by mapping the intensities of the beam spots with the locations of wafer 203, the processing system may reconstruct an image that reflects the internal or surface structures of wafer 203.

Imaging system 200 may be used for inspecting a wafer 203 on motorized sample stage 201 and includes an electron beam tool 104, as discussed above. Imaging system 200 may also include an image processing system 250 that includes an image acquirer 260, storage 270, and controller 109. Image acquirer 260 may include one or more processors. For example, image acquirer 260 may include a computer, server, mainframe host, terminals, personal computer, any kind of mobile computing devices, and the like, or a combination thereof. Image acquirer 260 may connect with a detector 206 of electron beam tool 104 through a medium such as an electrical-conductor, optical fiber cable, portable storage media, IR, Bluetooth, internet, wireless network, wireless radio, or a combination thereof. Image acquirer 260 may receive a signal from detector 206 and may construct an image. Image acquirer 260 may thus acquire images of wafer 203. Image acquirer 260 may also perform various post-processing functions, such as generating contours, superimposing indicators on an acquired image, and the like. Image acquirer 260 may perform adjustments of brightness and contrast, or the like, of acquired images. Storage 270 may be a storage medium such as a hard disk, cloud storage, random access memory (RAM), other types of computer readable memory, and the like. Storage 270 may be coupled with image acquirer 260 and may be used for saving scanned raw image data as original images, and post-processed images. Image acquirer 260 and storage 270 may be connected to controller 109. In some embodiments, image acquirer 260, storage 270, and controller 109 may be integrated together as one control unit.

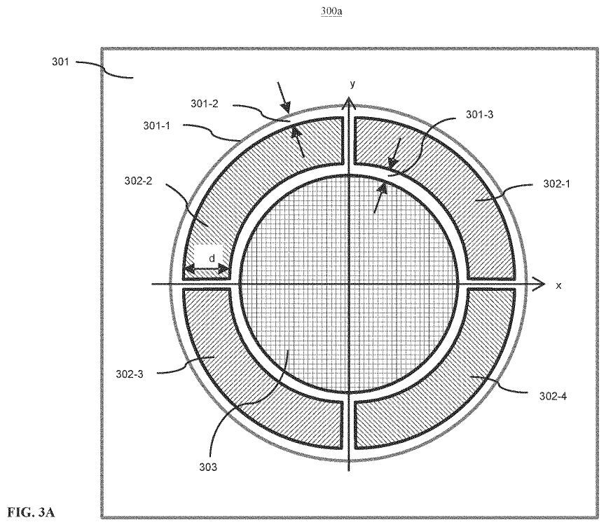

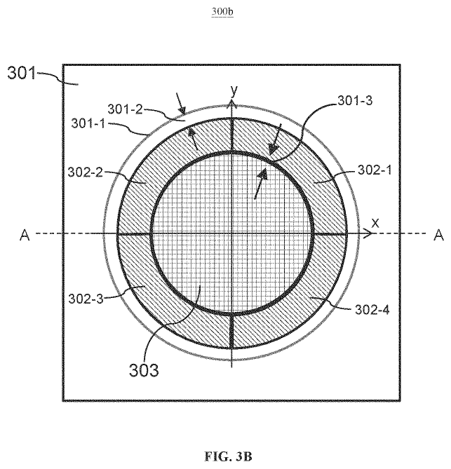

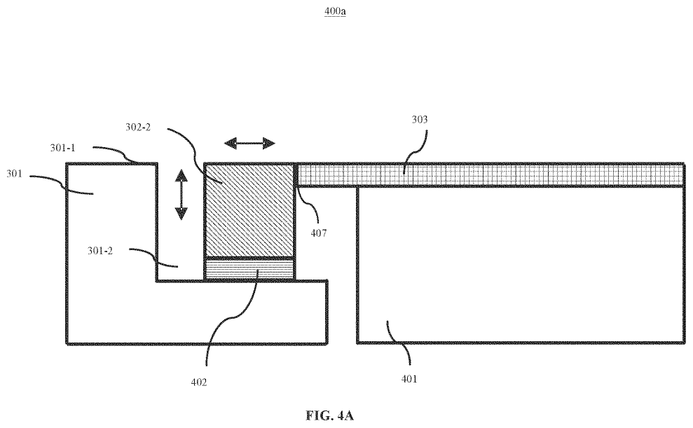

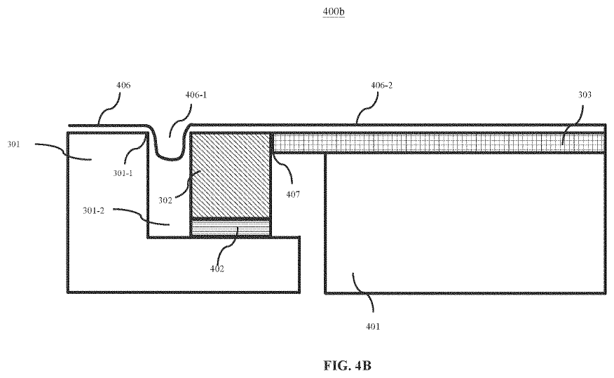

In some embodiments, image acquirer 260 may acquire one or more images of a sample based on an imaging signal received from detector 206. An imaging signal may correspond to a scanning operation for conducting charged particle imaging. An acquired image may be a single image including a plurality of imaging areas. The single image may be stored in storage 270. The single image may be an original image that may be divided into a plurality of regions. Each of the regions may include one imaging area containing a feature of wafer 203. As will be explained with regard to FIGS. 3A, 3B, 3A, and 4B, the elimination of e-field distortion is accomplished in two steps, 1) by closing the gap between the wafer and the HV ring, and 2) by adjusting the x-y position (including the height) of the conductive ring so that the wafer and the conductive ring are both at the same level. The zero gap between the wafer and the conductive ring and the same height of the wafer and the conductive ring eventually allow both to be supplied the same electric potential. The same electric potential extends the continuity of the same e-field as that of the wafer, leading to a uniform e-field at its edge.

FIG. 3A is an illustration of a top view of an example system during wafer loading, consistent with some embodiments of the present disclosure. Shown in FIG. 3A are a wafer stage 301, a wafer 303, and four segments 302-1, 302-2, 303-3, 302-4 of a conductive ring 302. It is appreciated that the conductive ring 302 has an inner portion and an outer portion. The inner portion of the conductive ring is the portion closer to the wafer 303, where any distortion of the e-field on the inner portion of conductive ring 302 could have a larger impact on the e-field on the outer portion of wafer 303. The outer portion of the conductive ring is the portion away from the wafer and any distortion of the e-field on the outer portion of conductive ring 302 may have little if any impact on the e-field on the outer portion of wafer 303. Also shown is an inner circle 301-1 of the wafer stage 301, which encloses the wafer 303 and the conductive ring 302. A gap between the inner circle 301-1 of the wafer and the conductive ring segments (302-1, 302-2, 302-3, 302-4) is shown by 301-2. Similarly, a gap between the conductive ring segments (302-1, 302-2, 302-3, 302-4) and the wafer 303 is shown by 301-3. A thickness of the conductive ring is shown by “d”. The thickness d is large enough so that the edge of the wafer 303 is far enough from the inner circle 301-1 to minimize the impact of the wafer edge e-field. In some embodiments, the thickness d can be a few millimeters or micrometers or any suitable value depending on design considerations. It is appreciated that the thickness d is predefined.

In some embodiments, during the loading of the wafer 303, the wafer stage 301 is kept stationary. The four segments (302-1, 302-2, 302-3 & 302-4) of the conductive ring 302 are then moved radially outward towards the inner circle 301-1 of the wafer stage 301 by leaving enough gap shown by 301-3 between the wafer and the conductive ring 302. The conductive ring segments can be moved individually, or all at once or in any combination. This helps avoid collision with the edge of the wafer 303. To avoid any potential collision, the conductive ring 302 segments are maintained at positions to allow a gap 301-2 between the inner circle 301-1 and the conductive ring segments. After the wafer 303 is loaded, the four segments (302-1, 302-2, 302-3 & 302-4) of the conductive ring can be moved radially inwards towards wafer 303 to make the gap 301-3 between them substantially negligible.

While it may be preferred that there is no gap or a zero gap between the conductive ring 302 and the wafer 303 and the conductive ring 302 and between adjacent segments (302-1, 302-2, 302-3 & 302-4) of the conductive ring 302, it is appreciated that some gap or gaps resulting from manufacturing flaws, design constraints, and goals may occur. In some embodiments, the disclosed system is designed to have a gap tolerance of 1 to 10 percent of the gap size, which is measured in micrometers.

A top view of the disclosed system after the wafer 303 is loaded is shown in FIG. 3B. As can be seen since the conductive ring segments have been moved closer to wafer 303, the gap 301-3 between the segments and wafer 303 is substantially minimal (e.g., a gap of zero or a few micrometers. In some embodiments, to avoid wafer collision, the gap may range from 1 to 10 micrometers. In general, a gap of 5-10 micrometers (a higher end of this range) may be suitable for an inspection application where image quality requirements are less stringent. A gap of 1-5 micrometers (a lower end of this range) may be suitable for a metrology application where a higher image quality is required or where image quality requirements are more stringent.

In some embodiments, conductive ring segments 302-1, 302-2, 302-3, and 302-4 are designed to have the same inner radius of curvature as the radius of the wafer 303, as a result of which the gap 301-3 can be fully closed. Moreover, the gap 301-2 between the inner circle and the conductive ring segments is larger in FIG. 3B compared to that in FIG. 3A.

Furthermore, the conductive ring 302 can be supplied with the same potential as the wafer 303, thereby extending the continuity of the e-field from the edge of the wafer 303 over the segments. More details about this will be explained with regard to FIGS. 4A and 4B.

While FIGS. 3A and 3B show conductive ring having four segments, it is appreciated that any number of segments can be used. For example, the minimal number of segments can be two. Moreover, it is appreciated that some of the segments can be in a fixed position. For example, it is appreciated that segment 302-4 can be in a fixed position with respect to the radial direction, while the other segments (i.e., segments 302-1, 302-2, and 302-3) can be moved radially inward and outwards.

The process of moving the conductive ring 302 as described above may be referred to as a conductive ring adjustment process. In some embodiments, in order to save time required for the conductive ring adjustment process, there can be two sets of wafer stages, a first wafer stage for performing the e-beam inspection and a second wafer stage for wafer loading and conductive ring adjustment process to be performed in parallel. That is, a wafer in the first wafer stage can undergo the e-beam inspection while a wafer in the second wafer stage can undergo wafer loading and the conductive ring adjustment process. It is appreciated that after the wafer in the first wafer stage has undergone the e-beam inspection, the conductive ring can be adjusted to remove the wafer and the first wafer stage can be moved to the wafer loading position for loading of a next wafer. In the same time frame, the second wafer stage, after undergoing the conductive ring adjustment process, can be positioned for inspection.

FIG. 4A illustrates a cross-sectional view of the system after the wafer 303 is loaded and the gap 301-3 between the conductive ring segment 302-2 and the wafer 303 has been substantially closed. FIG. 4A shows the wafer 303 placed on an e-chuck 401 and the conductive ring segment 302-2 placed on an adjustable mechanical assembly 402. The e-chuck 301 is used to apply the required electric potential to the wafer 303. In some embodiments, the mechanical assembly 402 is moved in any direction along x, y, or z axes relative to the wafer 303 and the wafer stage 301. The mechanism is adjusted in such a way that the x-y position of the conductive ring 302 is at least substantially similar to the x-y position of top surface of the wafer 303. It is appreciated that at this point in the process there is no gap between wafer edge 407 and the conductive ring segment 302-2, and both the top of wafer 303 and the top of conductive ring segment 302-2 are of substantially the same height. In other words, the top surfaces of both the conductive ring 302 and the wafer are substantially co-planar.

While it is preferred that the conductive ring 302 and the wafer 303 and all the adjacent segments (302-1, 302-2, 302-3 & 302-4) of the conductive ring 302 are at the exact same x-y position, it is appreciated that some difference in their x-y positions can occur based on manufacturing flaws, design constraints, etc. In some embodiments, the disclosed system is designed to have a x-y position tolerance of less than one micrometer.

In some embodiments, the disclosed system may include at least one position sensor to sense the x-y position of the conductive ring segment 302-2. The position sensor may send a control signal to the mechanical assembly 402 indicating whether the x-y position is less or more than the x-y position of the wafer 303. As explained earlier, the x-y position can include the height. After sensing the height being lower or higher than wafer 303, the mechanical assembly may be moved upward or downward until the height of the conductive ring 302-2 becomes substantially equal to the height of wafer 303.

At this stage in the process, the same voltage can be supplied to the conductive ring 302 and the wafer 303 so that the electric potential distribution near wafer edge 307 can be more uniform, the details of which will be explained with regard to FIG. 4B.

FIG. 4B illustrates the electric potential distribution 406 (406-1 and 406-2) on the wafer 303 and the conductive ring 302. Electric potential distribution 406-2 represents a more uniform potential, while electric potential distribution 406-1 represents a non-uniform (distorted) potential. As can be seen, there is a more uniform electric potential distribution 406-2 on top of the wafer 303 and the conductive ring 302. The non-uniform electric potential distribution 406-1 is in the gap 301-2, which is away from the wafer 303 and particularly wafer edge 407. Therefore, the non-uniform electric potential distribution 406-1 has a lesser impact on the charged-particle beam performance when doing inspection near a wafer edge. In other words, since the gap 301-2 is away from the wafer edge 407, the non-uniform electric potential distribution 406-1 and the resultant edge field impact to a charged particle beam can be minimized or eliminated.

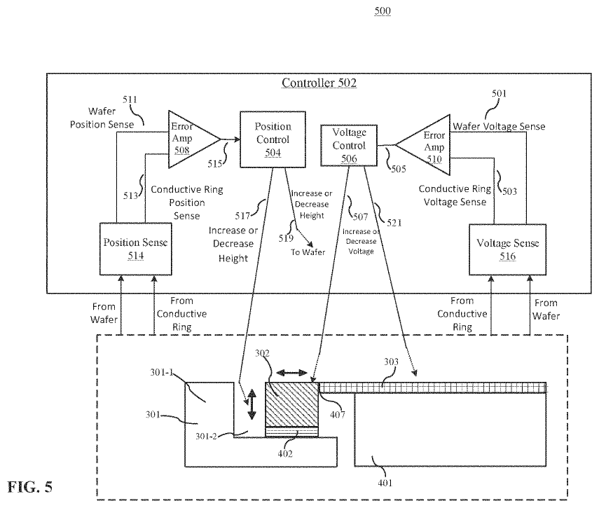

FIG. 5 is a schematic diagram illustrating an example controller and example sensors coupled to work with the system of 3A, 3B, 4A, or 4B, consistent with some embodiments of the present disclosure. As will be explained with regard to FIG. 5, in some embodiments, a controller including a voltage sense unit and a position sense unit may be implemented in the disclosed system. The voltage sense unit along with other circuitry may be used to ensure that the voltage applied to the conductive ring 302 is substantially the same as that of the wafer 303. In some examples, the two voltages may be adjusted by the circuitry independent of each other. Similarly, the position sense unit may be used to ensure that the x-y position of the conductive ring 302 is same as the x-y position of the wafer 302.

As shown the FIG. 5, system 500 includes a controller 502 configured to acquire information from the wafer 303 and the conductive ring 302.

The controller 502 is also configured to ensure that the conductive ring 302 is at the same x-y position as that of the wafer and is applied the same voltage as that of the wafer 303. The controller 502 may include a voltage sense unit 516, a voltage control unit 506, a position sense unit 514, a position control unit 504, and error amplifiers 508 and 510. The voltage sense unit 516, the error amplifier 510, and the voltage control unit 506 form a feedback loop for controlling the voltage of the conductive ring 302 or the voltage of the wafer 303 or both to assist with providing a substantially uniform e-field across conductive ring 302 and an outer portion of wafer 303 (including wafer edge 407). Similarly, the position sense unit 514, the error amplifier 508, and the position control unit 504 may form a feedback loop for controlling the x-y position of the conductive ring 302 and the gap between the conductive ring and the edge of the wafer, to assist with providing a substantially uniform e-field across conductive ring 302 and an outer portion of wafer 303 (including wafer edge 407).

The voltage sense unit 516 may include a first voltage sensor for sensing the wafer voltage and as a second voltage sensor for sensing the conductive ring. In other examples, there may be a single sensor for sensing both the voltages or a differential between the voltages. In some other examples, there may be a plurality of sensors. The controller 502 may be configured to acquire a wafer voltage information from the first voltage sensor and conductive ring voltage information from the second voltage sensor.

In general, the voltage sense unit 516 may sense voltages of the wafer 303 and the conductive ring 302 and generate a wafer voltage sense signal 501 representing a voltage of the wafer 303 and a conductive ring voltage signal 503 representing a voltage of the conductive ring, both of which may be fed to the error amplifier 510. The voltages of the wafer 303 and the conductive ring 302 may be sensed using any commonly known method in the art such as via an opto-coupler. It is appreciated that the error amplifier 510 may generate an error voltage 505 proportional to the difference between the voltages of the wafer 303 and the conductive ring 302. The error voltage 505 is fed to a voltage control unit 506, which may adjust the voltage of the conductive ring 302 by increasing or decreasing it (as shown by the signal 507) to substantially make the error voltage 505 equal to zero. The voltage control unit 506, may also adjust the voltage of the wafer 303 by increasing or decreasing it (as shown by the signal 521) to substantially make the error voltage 505 equal to zero. It is appreciated that a zero-error voltage may indicate that the voltage of the conductive ring 302 is the same or substantially the same as voltage of wafer 303. In other words, a zero error voltage may be an indication that there is no distortion in the e-field near the wafer edge 407 of the wafer 303.

Moreover, controller 502 may further be configured to acquire a wafer x-y position information and a conductive ring x-y position information from the position sense unit 514. The controller 502 may be further configured to adjust the x-y position of the conductive ring 302 by moving it upward or downward or the x-y position of the wafer 303 by moving it upward or downward so that a top surface of the conductive ring 302 is at least substantially co-planar with a top surface of the wafer 303. In some examples, the controller 502 may acquire the wafer x-y position information and the conductive ring x-y position information by the following exemplary implementation using its internal circuitry.

In some embodiments, the position sense unit 514 may include a plurality of sensors. In some embodiments, a first position sensor may be coupled to sense a level of the wafer 303 to generate a wafer position signal 511. The position sense unit 514 may include a second position sensor to sense a level of the conductive ring 302 to generate a conductive ring position signal 513. Both wafer position sense signal 511 and conductive ring position sense signal 513 may be provided to the error amplifier 508. The positions of the wafer 303 and the conductive ring 302 may be sensed using any commonly known method in the art such as via position or a motion sensor which may convert the position into an electrical signal such as voltage or current.

It is appreciated that the error amplifier 508 may generate an error voltage 515 proportional to the difference between the positions of the wafer 303 and the conductive ring 302. The error voltage 515 may be fed to a position control unit 504, which may adjust the position of the conductive ring 302 by increasing or decreasing it (as shown by a signal 517) to substantially make the error voltage 515 equal to substantially zero. The position control unit 504, may also adjust the position of the wafer 303 by increasing or decreasing it (as shown by a signal 519) to substantially make the error voltage 515 equal to substantially zero. It is appreciated that a zero-error voltage may indicate that the position of the conductive ring 302 is substantially the same position of the wafer 303. In other words, a zero error voltage may be an indication that there is a substantially uniform e-field near the edge of the wafer.

The controller 502 may include other circuitry or hardware or software (not shown) to control the voltage and the position of the conductive ring 302. For example, the controller may have a software lookup table that may include entries corresponding to error voltages 505 and 515. The voltage control unit 506 and the position control unit 504 may use the lookup table entries for adjusting the voltage or the position of conductive ring 302. In some embodiments, the conductive ring 302 and the mechanical assembly 402 can be made of materials including non-magnetic metallic materials, e.g., Titanium, Aluminum etc., or insulating materials with non-magnetic metallic coatings.

It should be noted that voltage sensing may include sensing any type of the electric characteristic such as a direct current (dc) or an alternating current (ac). A de circuit or an ac circuit may be used in this disclosure without falling outside the scope of this disclosure.

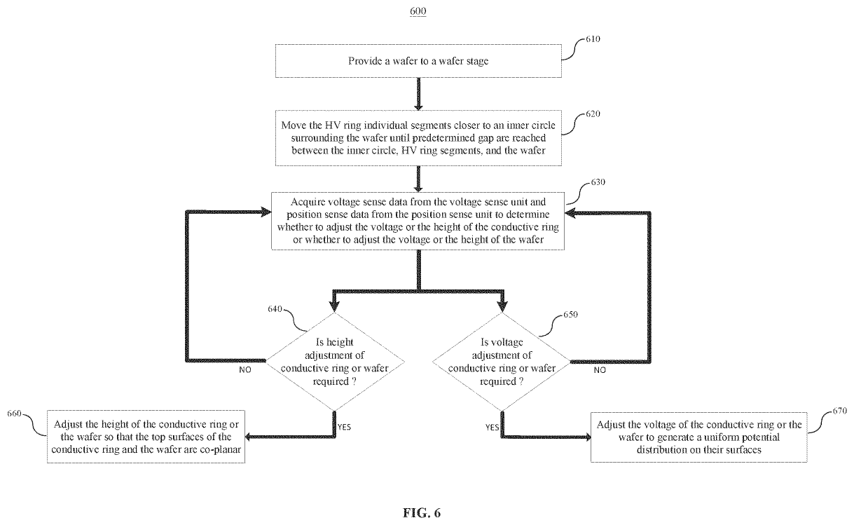

FIG. 6 is a flowchart illustrating an example method 600 for wafer grounding, consistent with some embodiments of the present disclosure. Method 600 may be performed by a controller that may be coupled with a charged particle beam apparatus (e.g., EBI system 100). For example, the controller may be controller 109 in FIG. 2 or controller 502 in FIG. 5. The controller may be programmed to implement a method 600.

At step 610, the wafer may be placed on a stage and an e-chuck. The wafer may be wafer 303 in FIG. 3A. In order to provide more space for placing the wafer, one or more segments (e.g., segments 302-1, 302-2, 302-3, and 302-4 of FIG. 3A) may be moved radially outward.

At step 620, one or more segments (e.g., segments 302-1, 302-2, 302-3, and 302-4 of FIG. 3B) of the conductive ring can be moved radially inward to surround the wafer until predetermined gaps are reached between the inner circle, conductive ring segments, and the wafer.

At step 630, voltage sense data and position sense data may be acquired to determine whether the position or the voltage of the conductive ring needs to be adjusted or whether the position or the voltage of the wafer needs to be adjusted. For example, referring back to FIG. 5, the wafer voltage sense signal 501 and the conductive ring voltage sense signal 503 from the voltage sense unit 516 may be acquired by the controller 502. Similarly, the wafer position sense signal 511 and the conductive ring position sense signal 513 from the position sense unit 514 may be acquired by the controller 502.

At step 640, it may be checked if position adjustment of the conductive ring or the wafer is required. If so, then the method may proceed to step 660. If not, then the method may go back to the step 630 to check if acquire position sense data.

At step 650, it may be checked if voltage adjustment of the conductive ring or the wafer is required. If so, then the method may proceed to step 670. If not, then the method may go back to the step 630 to check if acquire position sense data.

The steps 640 and 650 may be performed serially in any order or in parallel or in any combination based on design considerations and system performance.

At step 660 position of the conductive ring 302 can be adjusted relative to the wafer so that the top surfaces of the conductive ring and the wafer are co-planar. For example, referring back to FIG. 5, the controller 502 may increase or decrease the position of the conductive ring using the error amplifier 508 and the position control unit 504 based on the error voltage 515 and via an increase or decrease position signal 517. The controller 502 may increase or decrease the position of the wafer using the error amplifier 508 and the position control unit 504 based on the error voltage 515 and via an increase or decrease position signal 519.

At step 670, the voltage of the conductive ring 302 may be adjusted to generate a uniform potential distribution on their surfaces. For example, referring back to FIG. 5, the controller 502 may increase or decrease the voltage of the conductive ring using the error amplifier 510 and the voltage control unit 506 based on the error voltage 505.

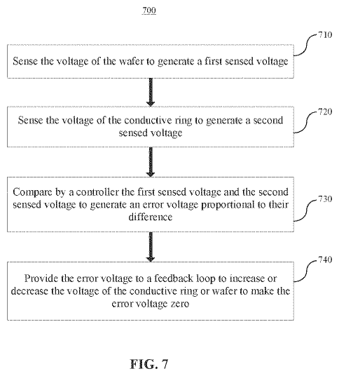

The step 670 will be explained in more details in FIG. 7.

FIG. 7 is a flowchart illustrating an example method 700 for creating a substantially uniform e-field near the wafer edge, consistent with some embodiments of the present disclosure. Specifically, the method 700 elaborates the step 670 of the FIG. 6.

At step 710, a voltage of the wafer can be sensed using a sensor (e.g., voltage sense unit 516 shown in FIG. 5) to generate a first sensed voltage.

At step 720, a voltage of the conductive ring can be sensed using the sensor (e.g., voltage sense unit 516 shown in FIG. 5) to generate a second sensed voltage.

At step 730, the first sensed voltage and the second sensed voltage can be compared by a controller (e.g., controller 502 shown in FIG. 5) and an error voltage (e.g., error voltage 505 shown in FIG. 5) proportional to the difference between the two voltages can be generated.

At step 740, the error voltage (e.g., error voltage 505 shown in FIG. 5) can be provided to a feedback loop to increase or decrease the voltage (e.g., signal 507) of the conductive ring or increase or decrease the voltage of the wafer (e.g., signal 521) to make the error voltage substantially zero.

It should also be noted that the apparatuses and systems as described in association with FIGS. 1-7 are not limited to be used in wafer inspection. Instead, they can be used for any system or apparatus that includes a high-voltage part and an adjustable mechanical assembly, and has a demand for uniform voltage distribution or elimination of any distortion near the wafer edge. For example, such system or apparatus may include, but not limited to, a SEM, a transmission electron microscopy (TEM), or an X-ray machine.

A non-transitory computer readable medium may be provided that stores instructions for a processor (for example, processor of controller 109 of FIG. 1) to carry out image processing, data processing, database management, graphical display, operations of a charged particle beam apparatus, or another imaging device, performing wafer inspection, moving conductive ring radially outward to create a space to place a wafer on a stage, placing wafer on the stage, moving the conductive ring radially inward until the conductive ring is within a predetermined distance from a wafer edge, sensing voltages of the conductive ring and the wafer, sensing the positions of the conductive ring and the wager, adjusting the voltage of the conductive ring to be equal to the voltage of the wafer to create a substantially uniform e-field, adjusting the position of the conductive ring to be equal to the position of the wafer to make the top surfaces of both co-planar, or the like. Common forms of non-transitory media include, for example, a floppy disk, a flexible disk, hard disk, solid state drive, magnetic tape, or any other magnetic data storage medium, a CD-ROM, any other optical data storage medium, any physical medium with patterns of holes, a RAM, a PROM, and EPROM, a FLASH-EPROM or any other flash memory, NVRAM, a cache, a register, any other memory chip or cartridge, and networked versions of the same.

The embodiments may further be described using the following clauses:
1. A method of inspecting a wafer comprising:
placing the wafer at a location on a stage;
moving one or more movable segments of a conductive ring inward in a radial direction to enable the conductive ring to be within a predetermined distance from an edge of the wafer; and adjusting a voltage applied to the conductive ring to enable the voltage applied to the conductive ring to be substantially equal to the voltage applied to the wafer to provide a substantially consistent electric field across an inner portion of the conductive ring and an outer portion of the wafer.
2. The method of clause 1 further comprising:
moving the conductive ring radially outward to increase an area of a location on the stage to place the wafer.
3. The method of any one of clauses 1 and 2, wherein the conductive ring includes one or more fixed segments and wherein moving the one or more movable segments, inward in a radial direction further comprises:
moving the one or more movable segments in a second radial direction to enable the wafer to be within a predetermined distance of the one or more fixed segments.
4. The method of any one of clauses 1-3, wherein the conductive ring is supported by a mechanical assembly.
5. The method of clause 4, wherein the mechanical assembly comprises a separate mechanical assembly for each segment of the conductive ring.
6. The method of clause 4, further comprising:
adjusting a height of the conductive ring using the mechanical assembly to cause a top surface of the conductive ring to be substantially co-planar with a top surface of the wafer.
7. The method of any one of clauses 1-6, further comprising:
acquiring wafer voltage information to generate a first sensed voltage,
acquiring conductive ring voltage information to generate a second sensed voltage,
comparing, by the controller, the first sensed voltage and the second sensed voltage, and
adjusting the voltage applied to the conductive ring or the voltage applied to the wafer based on the comparison.
8. The method of clause 7, wherein adjusting the voltage applied to the conductive ring or the voltage applied to the wafer based on the comparison further comprising:
increasing or decreasing the voltage applied to the conductive ring to be substantially similar to the voltage applied to the wafer.
9. The method of clause 7, wherein adjusting the voltage applied to the conductive ring or the voltage applied to the wafer based on the comparison further comprises:
increasing or decreasing the voltage applied to the wafer to be substantially similar to the voltage applied to the conductive ring.
10. The method of clause 7, further comprising: acquiring the wafer voltage information by a first voltage sensor and acquiring the conductive ring voltage information by a second voltage sensor.
11. The method of any one of clauses 1-10, further comprising: adjusting height of the conductive ring by moving the one or more movable segments of the conductive ring in an upward direction.
12. The method of any one of clauses 1-11, further comprising: adjusting the conductive ring height by moving the one or more movable segments of the conductive ring in a downward direction.
13. The method of any one of clauses 11 and 12, further comprising: acquiring wafer height information by a first position sensor.
14. The method of any one of clauses 11 and 12, further comprising: acquiring conductive ring height information by a second position sensor.
15. A system of inspecting a wafer, comprising:
a stage configured to support a wafer having a wafer edge;
a conductive ring of the stage, the conductive ring comprising: one or more movable segments configured to move radially inward to enable the conductive ring to be moved to be within a predetermined distance from the wafer edge; and
a controller including circuitry configured to adjust a voltage applied to the conductive ring or to a voltage applied to the wafer to enable the voltage applied to the conductive ring to be substantially similar to the voltage applied to the wafer to provide a substantially consistent electric field across an inner portion of the conductive ring and an outer portion of the wafer.
16. The system of clause 15, wherein the conductive ring is configured to move radially outward to increase an area of a location on the stage to place the wafer.
17. The system of any one of clauses 15 and 16, wherein the conductive ring being supported by a mechanical assembly.
18. The system of clause 17, wherein the mechanical assembly comprises a separate mechanical assembly for each segment of the conductive ring.
19. The system of any one of clauses 15-18, wherein the conductive ring comprises one or more fixed segments that are fixed in a radial direction and wherein the one or more movable segments are movable in a radial direction and are configured to enable the wafer to be within the predetermined distance of the one or more fixed segments.
20. The system of any one of clauses 15-19, wherein the predetermined distance is a few microns.
21. The system of any one of clauses 15-20, wherein the controller includes circuitry configured to adjust the voltage applied to the conductive ring and the voltage applied to the wafer independent of each other.
22. The system of clause 17, wherein the mechanical assembly is configured to move the conductive ring upward or downward such that the height of a top surface of each of the multiple segments and a top surface of the wafer are substantially co-planar.
23. The system of clause 18, wherein the mechanical assembly is configured to move each of the multiple segments upward.
24. The system of clause 18, wherein the mechanical assembly is configured to move each of the multiple segments downward.
25. The system of any one of clauses 15-24, wherein:
the controller includes circuitry configured to acquire wafer voltage information and generate a first sensed voltage; wherein
the controller includes circuitry configured to acquire conductive ring voltage information and to generate a second sensed voltage; and wherein
the controller includes circuitry configured to adjust the voltage applied to the conductive ring or the voltage applied to the wafer based on a comparison of the first sensed voltage and the second sensed voltage.
26. The system of clause 25, wherein the controller includes circuitry configured adjust the voltage applied to the conductive ring or the voltage applied to the wafer to provide a substantially consistent electric field across the one or more movable segments and the outer portion of the wafer.
27. The system of any one of clauses 15-26, wherein the one or more movable segments abut each other when moved radially inward.
28. The system of any one of clauses 15-27, wherein an inner radius of curvature when the conductive ring closes is substantially similar to a radius of the wafer.
29. The system of any one of clauses 15-28, wherein each of the one or more movable segments has a predefined thickness.
30. The system of clause 25, wherein to acquire the wafer voltage information, the controller includes circuitry configured to sense wafer voltage via a first voltage sensor.
31. The system of clause 25, wherein to acquire the conductive ring voltage information, the controller includes circuitry configured to sense the conductive ring voltage via a second voltage sensor.
32. A system of inspecting a wafer, comprising:
a stage configured to support a wafer having a wafer edge;
a conductive ring of the stage, the conductive ring comprising: one or more movable segments configured to move radially outward to increase an area of a location on the wafer holder to place the wafer and configured to move radially inward to enable the conductive ring to be moved to be within a predetermined distance from the wafer edge;
a controller including circuitry configured to adjust a height of the one or more movable segments of the conductive ring or a height of the wafer to enable a top surface of the conductive ring to be substantially co-planar with a top surface of the wafer.
33. The system of clause 32, wherein the conductive ring is configured to move radially outward to increase an area of a location on the stage to place the wafer.
34. The system of any one of clauses 32 and 33, wherein the conductive ring being supported by at least a mechanical assembly.
35. The system of clause 34, wherein the mechanical assembly comprises a separate mechanical assembly for each segment of the conductive ring.
36. The system of any one of clauses 32-35, wherein the conductive ring comprises one or more fixed segments that are fixed in a radial direction and wherein the one or more movable segments are movable in a radial direction and are configured to enable the wafer to be moved to be within the predetermined distance of the one or more segments.
37. The system of any one of clauses 32-36, wherein the controller includes circuitry configured to provide a substantially consistent electric field across an inner portion of the conductive ring and at an outer portion of the wafer.
38. The system of any one of clauses 32-37, wherein the predetermined distance is a few microns.
39. The system of any one of clauses 32-38, wherein the controller includes circuitry configured to adjust to move the conductive ring upward or downward such that the height of a top surface of each of the multiple segments and a top surface of the wafer are substantially co-planar.
40. The system of clause 34, wherein the mechanical assembly is configured to move each of the multiple segments upward.
41. The system of clause 34, wherein the mechanical assembly is configured to move each of the multiple segments downward.
42. The system of any one of clauses 32-41, wherein the one or more movable segments abut each other when moved radially inward.
43. The system of clause 36, wherein an inner radius of curvature of the conductive ring is substantially similar to radius of the wafer when the wafer is within the predetermined distance of the one or more segments.
44. The system of any one of clauses 32-43, wherein each of the one or more movable segments has a predefined thickness.
45. The system of any one of clauses 32-44, wherein:
the controller includes circuitry configured to acquire wafer height information and generate a first sensed height; wherein
the controller includes circuitry configured to acquire conductive ring height information and to generate a second sensed height; and wherein the controller includes circuitry configured to adjust the conductive ring height or the wafer height based on a comparison of the first sensed height and the second sensed height and further correct a difference between them.
46. The system of clause 45, wherein to acquire the wafer height information, the controller includes circuitry configured to sense a wafer height via a first position sensor.
47. The system of clause 45, wherein to acquire the conductive ring height information, the controller includes circuitry to sense the conductive ring height via a second position sensor.
48. A non-transitory computer-readable medium storing a set of instructions that are executable by at least one processor of a device to cause the device to perform a method comprising: placing the wafer at a location on a stage;
moving one or more movable segments of a conductive ring inward in a radial direction to enable the conductive ring to be within a predetermined distance from an edge of the wafer; and
adjusting a voltage applied to the conductive ring or to a voltage applied to the wafer so that to enable the voltage applied to the conductive ring to be substantially equal to the voltage applied to the wafer to provide a substantially consistent electric field across an inner portion of the conductive ring and an outer portion of the wafer.
49. The non-transitory computer-readable medium of clause 48, wherein the set of instructions that are executable by the at least one processor to cause the device to further perform:
moving the one or more movable segments of the conductive ring radially outward to increase an area of a location on the stage to place the wafer.
50. The non-transitory computer-readable medium of any one of clauses 48 and 49, wherein the set of instructions that are executable by the at least one processor to cause the device to further perform:
moving the one or more movable segments inward in a radial direction which further comprises:
moving the one or more movable segments in a second radial direction to enable the wafer to be within a predetermined distance of a one or more fixed segments included in the conductive ring.
51. The non-transitory computer-readable medium of any one of clauses 48-50, wherein the conductive ring is supported by a mechanical assembly.
52. The non-transitory computer-readable medium of any one of clauses 48-51, wherein each segment of the one or more movable segments of the conductive ring is supported by a separate mechanical assembly.
53. The non-transitory computer-readable medium of clause 50, wherein the conductive ring comprises one or more fixed segments that are fixed in a radial direction and wherein the set of instructions that are executable by the at least one processor to cause the device to further perform:
moving the one or more movable segments in a radial direction to enable the wafer to be within the predetermined distance of the one or more fixed segments.
54. The non-transitory computer-readable medium of clause 51, wherein the set of instructions that are executable by the at least one processor to cause the device to further perform:
configuring the mechanical assembly to move the one or more movable segments of the conductive ring upward or downward or such that the height of a top surface of each of the one or more movable segments and a top surface of the wafer are substantially co-planar.
55. The non-transitory computer-readable medium any one of clauses 48-54, wherein the set of instructions that are executable by the at least one processor to cause the device to further perform:
acquiring wafer voltage information to generate a first sensed voltage, acquiring conductive ring voltage information to generate a second sense voltage, comparing by the controller the first sensed voltage and the second sensed voltage, and
adjusting the voltage applied to the conductive ring or the voltage applied to the wafer based on the comparison.
56. The non-transitory computer-readable medium of clause 53, wherein the set of instructions that are executable by the at least one processor to cause the device to further perform:
increasing or decreasing the voltage applied to the conductive ring to be substantially similar to the voltage applied to the wafer.
57. The non-transitory computer-readable medium of clause 54, wherein the set of instructions that are executable by the at least one processor to cause the device to further perform:
increasing or decreasing the voltage applied to the wafer to be substantially similar to the voltage applied to the conductive ring.
58. The non-transitory computer-readable medium of clause 55, wherein the set of instructions that are executable by the at least one processor to cause the device to further perform:
acquiring the wafer voltage information by a first voltage sensor and acquiring the conductive ring voltage information by a second voltage sensor.
59. The non-transitory computer-readable medium of clause 52, wherein the set of instructions that are executable by the at least one processor to cause the device to further perform:
adjusting the height of the one or more movable segments of the conductive ring by moving the conductive ring in an upward direction.
60. The non-transitory computer-readable medium of clause 52, wherein the set of instructions that are executable by the at least one processor to cause the device to further perform:
adjusting the height of the one or more movable segments of the conductive ring by moving the one or more movable segments of the conductive ring in a downward direction.
61. The non-transitory computer-readable medium of clause 48, wherein the set of instructions that are executable by the at least one processor to cause the device to further perform:
acquiring wafer height information by a first position sensor.
62. The non-transitory computer-readable medium of clause 48, wherein the set of instructions that are executable by the at least one processor to cause the device to further perform:
acquiring conductive ring height information by a second position sensor.
63. A method of inspecting a wafer, comprising:
placing the wafer at a location on a stage;
moving one or more movable segments of a conductive ring inward in a radial direction to enable the conductive ring to be within a predetermined distance from an edge of the wafer; and
adjusting a height of the conductive ring or a height of the wafer to enable a top surface of the conductive ring to be substantially co-planar with a top surface of the wafer.
64. A non-transitory computer-readable medium storing a set of instructions that are executable by at least one processor of a device to cause the device to perform a method comprising: placing the wafer at a location on a stage;
moving one or more movable segments of a conductive ring inward in a radial direction to enable the conductive ring to be within a predetermined distance from an edge of the wafer; and
65. adjusting a height of the one or more movable segments of the conductive ring or a height of the wafer to enable a top surface of the conductive ring to be substantially co-planar with a top surface of the wafer.

The block diagrams in the figures illustrate the architecture, functionality, and operation of possible implementations of systems, methods, and computer hardware or software products according to various example embodiments of the present disclosure. In this regard, each block in a flowchart or block diagram may represent a module, segment, or portion of code, which includes one or more executable instructions for implementing the specified logical functions. It should be understood that in some alternative implementations, functions indicated in a block may occur out of order noted in the figures. For example, two blocks shown in succession may be executed or implemented substantially concurrently, or two blocks may sometimes be executed in reverse order, depending upon the functionality involved. Some blocks may also be omitted. It should also be understood that each block of the block diagrams, and combination of the blocks, may be implemented by special purpose hardware-based systems that perform the specified functions or acts, or by combinations of special purpose hardware and computer instructions.

It will be appreciated that the embodiments of the present disclosure are not limited to the exact construction that has been described above and illustrated in the accompanying drawings, and that various modifications and changes may be made without departing from the scope thereof.

1. A non-transitory computer-readable medium storing a set of instructions that are executable by at least one processor of a device to cause the device to perform a method comprising:
placing a wafer at a location on a stage;
moving one or more movable segments of a conductive ring inward in a radial direction to enable the conductive ring to be within a predetermined distance from an edge of the wafer; and
adjusting a voltage applied to the conductive ring or to a voltage applied to the wafer so that to enable the voltage applied to the conductive ring to be substantially equal to the voltage applied to the wafer to provide a substantially consistent electric field across an inner portion of the conductive ring and an outer portion of the wafer.

2. The non-transitory computer-readable medium of claim 1, wherein the set of instructions that are executable by the at least one processor to cause the device to further perform:
moving the one or more movable segments of the conductive ring radially outward to increase an area of a location on the stage to place the wafer.

3. The non-transitory computer-readable medium of claim 1, wherein the set of instructions that are executable by the at least one processor to cause the device to further perform:
moving the one or more movable segments inward in a radial direction which further comprises:
moving the one or more movable segments in a second radial direction to enable the wafer to be within a predetermined distance of a one or more fixed segments included in the conductive ring.

4. The non-transitory computer-readable medium of claim 1, wherein the conductive ring is supported by a mechanical assembly.

5. The non-transitory computer-readable medium of claim 1, wherein each segment of the one or more movable segments of the conductive ring is supported by a separate mechanical assembly.

6. The non-transitory computer-readable medium of claim 3, wherein the conductive ring comprises one or more fixed segments that are fixed in a radial direction and wherein the set of instructions that are executable by the at least one processor to cause the device to further perform:
moving the one or more movable segments in a radial direction to enable the wafer to be within the predetermined distance of the one or more fixed segments.

7. The non-transitory computer-readable medium of claim 4, wherein the set of instructions that are executable by the at least one processor to cause the device to further perform:
configuring the mechanical assembly to move the one or more movable segments of the conductive ring upward or downward or such that the position of a top surface of each of the one or more movable segments and a top surface of the wafer are substantially co-planar.

8. The non-transitory computer-readable medium claim 1, wherein the set of instructions that are executable by the at least one processor to cause the device to further perform:
acquiring wafer voltage information to generate a first sensed voltage,
acquiring conductive ring voltage information to generate a second sense voltage,
comparing the first sensed voltage and the second sensed voltage, and
adjusting the voltage applied to the conductive ring or the voltage applied to the wafer based on the comparison.

9. The non-transitory computer-readable medium of claim 6, wherein the set of instructions that are executable by the at least one processor to cause the device to further perform:
increasing or decreasing the voltage applied to the conductive ring to be substantially similar to the voltage applied to the wafer.

10. The non-transitory computer-readable medium of claim 7, wherein the set of instructions that are executable by the at least one processor to cause the device to further perform:
increasing or decreasing the voltage applied to the wafer to be substantially similar to the voltage applied to the conductive ring.

11. The non-transitory computer-readable medium of claim 8, wherein the set of instructions that are executable by the at least one processor to cause the device to further perform:
acquiring the wafer voltage information by a first voltage sensor and acquiring the conductive ring voltage information by a second voltage sensor.

12. The non-transitory computer-readable medium of claim 5, wherein the set of instructions that are executable by the at least one processor to cause the device to further perform:
adjusting the position of the one or more movable segments of the conductive ring by moving the conductive ring in an upward direction.

13. The non-transitory computer-readable medium of claim 5, wherein the set of instructions that are executable by the at least one processor to cause the device to further perform:
adjusting the position of the one or more movable segments of the conductive ring by moving the one or more movable segments of the conductive ring in a downward direction.

14. The non-transitory computer-readable medium of claim 1, wherein the set of instructions that are executable by the at least one processor to cause the device to further perform:
acquiring wafer position information by a first position sensor.

15. A system of inspecting a wafer, comprising:
a stage configured to support a wafer having a wafer edge;
a conductive ring of the stage, the conductive ring comprising one or more movable segments configured to move radially inward to enable the conductive ring to be moved to be within a predetermined distance from the wafer edge; and
a controller including circuitry configured to adjust a voltage applied to the conductive ring or to a voltage applied to the wafer to enable the voltage applied to the conductive ring to be substantially similar to the voltage applied to the wafer to provide a substantially consistent electric field across an inner portion of the conductive ring and an outer portion of the wafer.

16. A system of inspecting a wafer, comprising:
a stage configured to support a wafer having a wafer edge;
a conductive ring of the stage, the conductive ring comprising: one or more movable segments configured to move radially outward to increase an area of a location on a wafer holder to place the wafer and configured to move radially inward to enable the conductive ring to be moved to be within a predetermined distance from the wafer edge;
a controller including circuitry configured to adjust a height of the one or more movable segments of the conductive ring or a height of the wafer to enable a top surface of the conductive ring to be substantially co-planar with a top surface of the wafer.

17. The system of claim 16, wherein the conductive ring is configured to move radially outward to increase an area of a location on the stage to place the wafer.

18. The system of claim 16, wherein the conductive ring being supported by at least a mechanical assembly.

19. The system of claim 18, wherein the mechanical assembly comprises a separate mechanical assembly for each segment of the conductive ring.

20. The system of claim 16, wherein the conductive ring comprises one or more fixed segments that are fixed in a radial direction and wherein the one or more movable segments are movable in a radial direction and are configured to enable the wafer to be moved to be within the predetermined distance of the one or more segments.
